(19) United States
(12) Patent Application Publication
(10) Pub. No.: US 2024/0105714 A1
(43) Pub. Date: Mar. 28, 2024

(54) SEMICONDUCTOR DEVICE INCLUDING VERTICAL SUPPORTING STRUCTURE

(71) Applicant: NANYA TECHNOLOGY CORPORATION, NEW TAIPEI CITY (TW)

(72) Inventor: WEN-CHIEH WANG, TAOYUAN CITY (TW)

(21) Appl. No.: 17/953,636

(22) Filed: Sep. 27, 2022

(51) Int. Cl. H01L 27/08; H01G 4/012; H01G 4/38

(52) U.S. Cl. CPC H01L 27/0805; H01G 4/012; H01G 4/38

(57) ABSTRACT

A semiconductor device and a method for manufacturing the same are provided. The semiconductor device includes a substrate, a lower horizontal supporting layer, an upper horizontal supporting layer, a vertical supporting structure, and a first capacitor electrode. The lower horizontal supporting layer is disposed on the substrate. The upper horizontal supporting layer is disposed on the lower horizontal supporting layer. The vertical supporting structure extends between the lower horizontal supporting layer and the upper horizontal supporting layer. The first capacitor electrode is disposed on the substrate and extends from the lower horizontal supporting layer to the upper horizontal supporting layer.

### TECHNICAL FIELD

The present disclosure relates to a semiconductor device and a method for manufacturing the same, and more particularly, to a semiconductor device with a vertical supporting structure to support capacitor structures.

### DISCUSSION OF THE BACKGROUND

With the rapid growth of the electronics industry, integrated circuits (ICs) have achieved high performance and miniaturization. Technological advances in IC materials and design have produced generations of ICs with smaller and more complex circuits.

During the formation of capacitor structures, sacrificial layers are formed to define the spaces between capacitor electrodes to be formed. When sacrificial layers are removed, the intermediate structure is prone to collapsing. In order to solve this problem, a new type of semiconductor device is required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate, a lower horizontal supporting layer, an upper horizontal supporting layer, a vertical supporting structure, and a first capacitor electrode. The lower horizontal supporting layer is disposed on the substrate. The upper horizontal supporting layer is disposed on the lower horizontal supporting layer. The vertical supporting structure extends between the lower horizontal supporting layer and the upper horizontal supporting layer. The first capacitor electrode is disposed on the substrate and extends from the lower horizontal supporting layer to the upper horizontal supporting layer.

Another aspect of the present disclosure provides another semiconductor device. The semiconductor device includes a substrate, a lower horizontal supporting layer, an upper horizontal supporting layer, a first vertical supporting structure, a second vertical supporting structure, and a plurality of capacitor structures. The lower horizontal supporting layer is disposed on the substrate. The upper horizontal supporting layer is disposed on the lower horizontal supporting layer. The first vertical supporting structure extends between the lower horizontal supporting layer and the upper horizontal supporting layer. The second vertical supporting structure extends between the lower horizontal supporting layer and the upper horizontal supporting layer. Each capacitor structure is disposed between the first vertical supporting structure and the second vertical supporting structure.

Another aspect of the present disclosure provides a method of manufacturing a semiconductor device. The method includes providing a substrate. The method also includes forming a first horizontal supporting layer on the substrate. The method further includes forming a first sacrificial layer on the first horizontal supporting layer. In addition, the method includes removing a portion of the first sacrificial layer to form a first opening. The method also includes forming a first pillar filling the first opening and a second horizontal supporting layer on the first sacrificial layer. The method further includes patterning the second horizontal supporting layer, the first sacrificial layer, and the first horizontal supporting layer to define a second opening. The method includes forming a first capacitor electrode within the second opening and removing the first sacrificial layer.

The embodiments of the present disclosure provide a semiconductor device. The semiconductor device may include a vertical supporting structure to connect horizontal supporting layers. The vertical supporting structure can reinforce the overall structure of a semiconductor device. For example, when sacrificial layers are removed to define a space for an upper capacitor electrode, the framework composed of horizontal supporting layers and a lower capacitor electrode is prone to collapsing, resulting in a lower semiconductor device manufacturing yield. In such a condition, the vertical supporting structure can provide a more rigid structure to prevent the framework from collapsing. As a result, the semiconductor device manufacturing yield can be enhanced.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a top view of a semiconductor device, in accordance with some embodiments of the present disclosure.

FIG. 1B is a cross-sectional view along line A-A′ of the semiconductor device as shown in FIG. 1A, in accordance with some embodiments of the present disclosure.

FIG. 2A is a top view of a semiconductor device, in accordance with some embodiments of the present disclosure.

FIG. 2B is a cross-sectional view along line B-B′ of the semiconductor device as shown in FIG. 2A, in accordance with some embodiments of the present disclosure.

FIG. 3A is a top view of a semiconductor device, in accordance with some embodiments of the present disclosure.

FIG. 3B is a cross-sectional view along line C-C′ of the semiconductor device as shown in FIG. 3A, in accordance with some embodiments of the present disclosure.

FIG. 4 is a flowchart illustrating a method of manufacturing a semiconductor device, in accordance with some embodiments of the present disclosure.

FIG. 5A and FIG. 5B illustrate one or more stages of an example of a method for manufacturing a semiconductor device according to some embodiments of the present disclosure.

FIG. 6A and FIG. 6B illustrate one or more stages of an example of a method for manufacturing a semiconductor device according to some embodiments of the present disclosure.

FIG. 7A and FIG. 7B illustrate one or more stages of an example of a method for manufacturing a semiconductor device according to some embodiments of the present disclosure.

FIG. 8A and FIG. 8B illustrate one or more stages of an example of a method for manufacturing a semiconductor device according to some embodiments of the present disclosure.

FIG. 9A and FIG. 9B illustrate one or more stages of an example of a method for manufacturing a semiconductor device according to some embodiments of the present disclosure.

FIG. 10A and FIG. 10B illustrate one or more stages of an example of a method for manufacturing a semiconductor device according to some embodiments of the present disclosure.

FIG. 11A and FIG. 11B illustrate one or more stages of an example of a method for manufacturing a semiconductor device according to some embodiments of the present disclosure.

FIG. 12A and FIG. 12B illustrate one or more stages of an example of a method for manufacturing a semiconductor device according to some embodiments of the present disclosure.

FIG. 13A and FIG. 13B illustrate one or more stages of an example of a method for manufacturing a semiconductor device according to some embodiments of the present disclosure.

FIG. 14A and FIG. 14B illustrate one or more stages of an example of a method for manufacturing a semiconductor device according to some embodiments of the present disclosure.

FIG. 15A and FIG. 15B illustrate one or more stages of an example of a method for manufacturing a semiconductor device according to some embodiments of the present disclosure.

FIG. 16A and FIG. 16B illustrate one or more stages of an example of a method for manufacturing a semiconductor device according to some embodiments of the present disclosure.

FIG. 17A and FIG. 17B illustrate one or more stages of an example of a method for manufacturing a semiconductor device according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

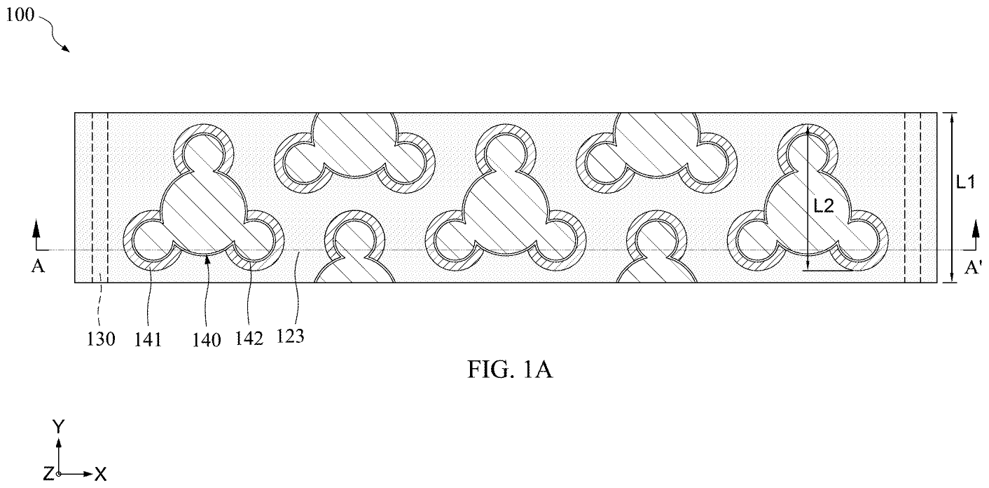

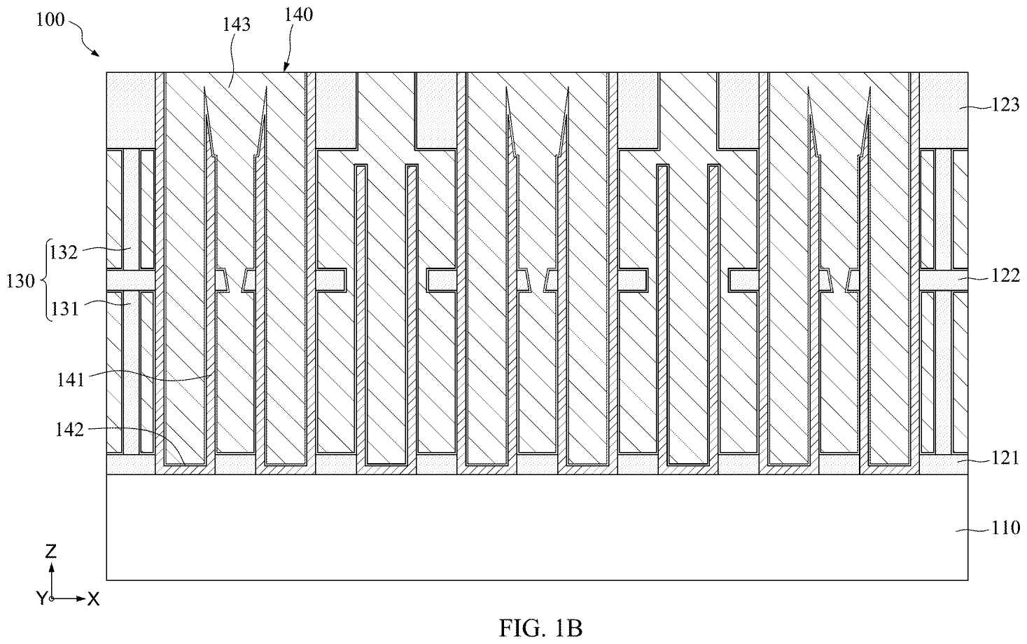

Referring to FIG. 1A and FIG. 1B, FIG. 1A is a top view of a semiconductor device 100, and FIG. 1B is a cross-sectional view along line A-A′ of the semiconductor device 100 as shown in FIG. 1A, in accordance with some embodiments of the present disclosure. It should be noted that some elements or features are omitted from FIG. 1A for brevity.

In some embodiments, the semiconductor device 100 may include a substrate 110, horizontal supporting layers 121, 122, and 123, a vertical supporting structure 130, as well as a plurality of capacitor structures 140.

The substrate 110 may be a semiconductor substrate, such as a bulk semiconductor, a semiconductor-on-insulator (SOI) substrate, or the like. The substrate 110 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 110 may have a multilayered structure.

Some elements are formed within or on the substrate 110. For example, transistors, conductive traces, contact plugs and/or other elements may be formed within or on the substrate 110.

In some embodiments, the horizontal supporting layer 121 may be disposed on the substrate 110. In some embodiments, the horizontal supporting layer 121 may also be referred to as a lower horizontal supporting layer.

In some embodiments, the horizontal supporting layer 122 may be disposed on the substrate 110. In some embodiments, the horizontal supporting layer 122 may be disposed over the horizontal supporting layer 121. In some embodiments, the horizontal supporting layer 122 may also be referred to as a middle horizontal supporting layer.

In some embodiments, the horizontal supporting layer 123 may be disposed on the substrate 110. In some embodiments, the horizontal supporting layer 123 may be disposed over the horizontal supporting layer 122. In some embodiments, the horizontal supporting layer 123 may also be referred to as an upper horizontal supporting layer.

In some embodiments, the horizontal supporting layers 121, 122, and 123 may be spaced apart from each other. In some embodiments, the horizontal supporting layers 121, 122, and 123 may be utilized to define the patterns of a capacitor dielectric and an upper electrode of the capacitor structure 140.

Each of the horizontal supporting layers 121, 122, and 123 may include silicon nitride (Si₃N₄), silicon oxide (SiO₂), silicon oxynitride (N₂OSi₂), silicon nitride oxide (N₂OSi₂), or other suitable materials. In some embodiments, the horizontal supporting layers 121, 122, and 123 may have the same material. In some embodiments, the horizontal supporting layers 121, 122, and 123 may define openings in a top view. The capacitor structure 140 may be disposed within the openings defined by the horizontal supporting layers 121, 122, and 123.

The vertical supporting structure 130 may be disposed on the substrate 110. In some embodiments, the vertical supporting structure 130 may be configured to support the horizontal supporting layers 121, 122, and 123. In some embodiments, the vertical supporting structure 130 may be disposed at a peripheral region (not annotated) of the semiconductor device 100. The vertical supporting structure 130 may extend along the Y-direction and pass through a plurality of capacitor structures 140.

In some embodiments, the pillar 131 may be configured to support the horizontal supporting layer 122. In some embodiments, the pillar 131 may extend between the horizontal supporting layers 121 and 122. In some embodiments, the pillar 131 may connect the horizontal supporting layers 121 and 122. In some embodiments, the pillar 131 may be in contact with the horizontal supporting layer 121. In some embodiments, the pillar 131 may be in contact with the horizontal supporting layer 122.

In some embodiments, the pillar 131 may include a dielectric material, such as silicon nitride (Si₃N₄), silicon oxide (SiO₂), silicon oxynitride (N₂OSi₂), silicon nitride oxide (N₂OSi₂), or other suitable materials. In some embodiments, the material of the pillar 131 may be the same as that of the horizontal supporting layer 122, which may simplify manufacturing processes. In some embodiments, the material of the pillar 131 may be different from that of the horizontal supporting layer 122. In some embodiments, the pillar 131 may include a conductive material, such as tungsten (W), copper (Cu), ruthenium (Ru), iridium (Ir), nickel (Ni), osmium (Os), ruthenium (Rh), aluminum (Al), molybdenum (Mo), cobalt (Co), alloys thereof, or a combination thereof.

In some embodiments, the pillar 132 may be configured to support the horizontal supporting layer 123. In some embodiments, the pillar 132 may be disposed directly over the pillar 131. In some embodiments, the pillar 132 may extend between the horizontal supporting layers 122 and 123. In some embodiments, the pillar 132 may connect the horizontal supporting layers 122 and 123. In some embodiments, the pillar 132 may be in contact with the horizontal supporting layer 122. In some embodiments, the pillar 132 may be in contact with the horizontal supporting layer 123.

In some embodiments, the pillar 132 may include a dielectric material, such as silicon nitride (Si₃N₄), silicon oxide (SiO₂), silicon oxynitride (N₂OSi₂), silicon nitride oxide (N₂OSi₂), or other suitable materials. In some embodiments, the material of the pillar 132 may be the same as that of the horizontal supporting layer 123, which may simplify manufacturing processes. In some embodiments, the pillar 132 may include a conductive material, such as tungsten (W), copper (Cu), ruthenium (Ru), iridium (Ir), nickel (Ni), osmium (Os), ruthenium (Rh), aluminum (Al), molybdenum (Mo), cobalt (Co), alloys thereof, or a combination thereof. In some embodiments, the material of the pillar 132 may be different from that of the horizontal supporting layer 123. In some embodiments, the material of the pillar 132 may be the same as that of the pillar 131. In some embodiments, the material of the pillar 132 may be different from that of the pillar 131.

Each of the capacitor structures 140 may be disposed within an opening defined by the horizontal supporting layers 121, 122, and/or 123. In some embodiments, the capacitor structure 140 may be disposed within an array region (not annotated) of the semiconductor device 100. Each of the capacitor structures 140 may include a capacitor electrode 141, a capacitor dielectric 142, and a capacitor electrode 143.

In some embodiments, the capacitor electrode 141 may be disposed on and in contact with a lateral surface (not annotated in the figures) of the horizontal supporting layer 121. In some embodiments, the capacitor electrode 141 may be disposed on and in contact with a lateral surface (not annotated in the figures) of the horizontal supporting layer 122. In some embodiments, the capacitor electrode 141 may be disposed on and in contact with a lateral surface (not annotated in the figures) of the horizontal supporting layer 123. In some embodiments, the capacitor electrode 141 may be spaced apart from the vertical supporting structure 130. In some embodiments, the capacitor electrode 141 may be spaced apart from the pillar 131. In some embodiments, the capacitor electrode 141 may be spaced apart from the pillar 132. In some embodiments, the capacitor electrode 141 may be spaced apart from the vertical supporting structure 130 by the capacitor dielectric 142. In some embodiments, the capacitor electrode 141 may be spaced apart from the vertical supporting structure 130 by the capacitor electrode 143.

The capacitor electrode 141 may include a conductive material(s), such as doped polysilicon, conductive metal nitride (e.g., titanium nitride, tantalum nitride, tungsten nitride, or the like), metal (e.g., ruthenium, iridium, titanium, tantalum, or the like), and conductive metal oxide (e.g., iridium oxide or the like). The capacitor electrode 141 may also be referred to as a lower capacitor electrode.

In some embodiments, the capacitor electrode 141 may include a tapered portion 141p. In some embodiments, the tapered portion 141p may be located at the top of the capacitor electrode 141. In some embodiments, the tapered portion 141p may be spaced apart from the horizontal supporting layer 123. In some embodiments, the tapered portion 141p may be spaced apart from the vertical supporting structure 130. In some embodiments, the tapered portion 141p may be lower than the topmost surface (not annotated in the figures) of the capacitor electrode 141. In some embodiments, the tapered portion 141p may be tapered far away from the substrate 110.

In some embodiments, the capacitor dielectric 142 may be conformally disposed on the capacitor electrode 141. The capacitor dielectric 142 may be disposed on and in contact with the horizontal supporting layer 121. The capacitor dielectric 142 may be disposed on and in contact with the horizontal supporting layer 122. The capacitor dielectric 142 may be disposed on and in contact with the horizontal supporting layer 123. In some embodiments, the capacitor dielectric 142 may be disposed on and in contact with the vertical supporting structure 130. In some embodiments, the capacitor dielectric 142 may be disposed on and in contact with the pillar 131. In some embodiments, the capacitor dielectric 142 may be disposed on and in contact with the pillar 132. The capacitor dielectric 142 may include silicon oxide, tungsten oxide, copper oxide, aluminum oxide, hafnium oxide, or the like.

The capacitor electrode 143 may be disposed on the capacitor dielectric 142. The capacitor electrode 143 may be spaced apart from the capacitor electrode 141 by the capacitor dielectric 142. The capacitor electrode 143 may be spaced apart from the horizontal supporting layers 121, 122, and 123 by the capacitor dielectric 142. In some embodiments, the capacitor electrode 143 may be spaced apart from the vertical supporting structure 130. In some embodiments, the capacitor electrode 143 may be spaced apart from the pillar 131. In some embodiments, the capacitor electrode 143 may be spaced apart from the pillar 132. The capacitor electrode 143 may include conductive material(s), such as doped polysilicon, conductive metal nitride (e.g., titanium nitride, tantalum nitride, tungsten nitride, or the like), metal (e.g., ruthenium, iridium, titanium, tantalum, or the like), and conductive metal oxide (e.g., iridium oxide or the like). In some embodiments, the capacitor electrode 143 may include a multilayered structure.

In some embodiments, a plurality of capacitor structures 140 may be disposed between two adjacent vertical supporting structures 130. The vertical supporting structure 130 may have a length L1 along the Y-direction. The capacitor structure 140 may have a length L2 along the Y-direction. In some embodiments, the length L1 of the vertical supporting structure 130 may be greater than the length L2 of the capacitor structure 140 along the Y-direction.

In the embodiments of the present disclosure, a semiconductor device (e.g., 100) may include a vertical supporting structure (e.g., 130) to connect horizontal supporting layers (e.g., 121, 122, and/or 123). The vertical supporting structure can reinforce the overall structure of the semiconductor device, which thereby enhances the semiconductor device manufacturing yield.

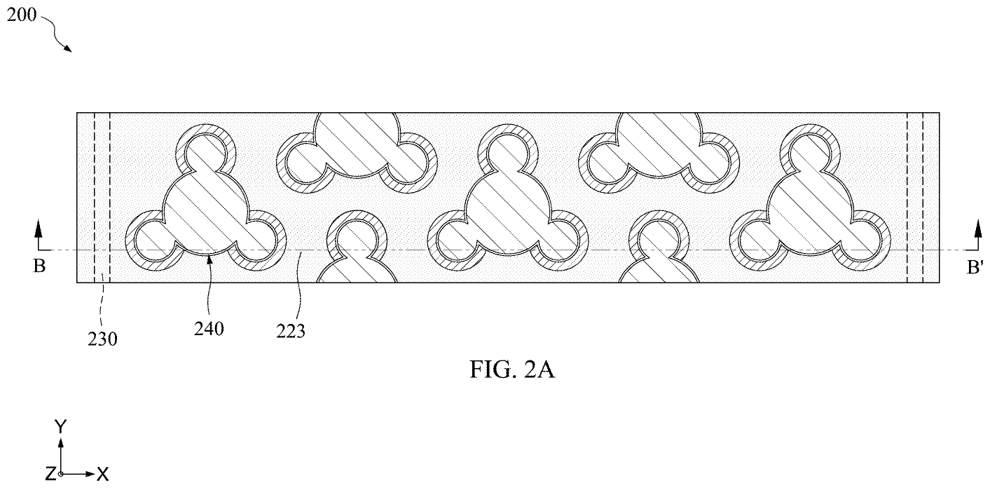

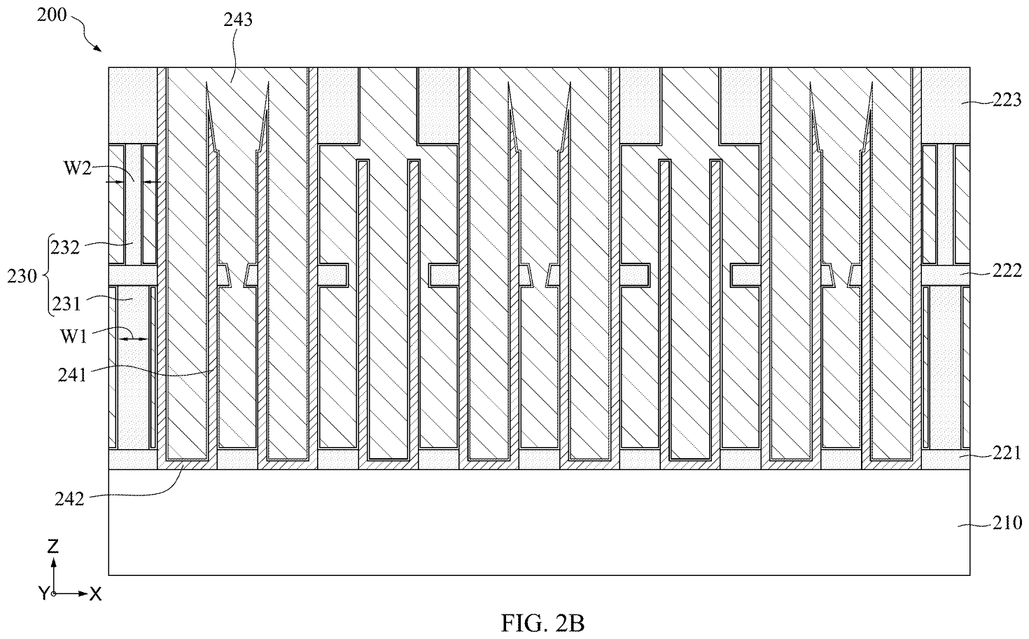

Referring to FIG. 2A and FIG. 2B, FIG. 2A is a top view of a semiconductor device 200, and FIG. 2B is a cross-sectional view along line B-B′ of the semiconductor device 200 as shown in FIG. 2A, in accordance with some embodiments of the present disclosure.

In some embodiments, the semiconductor device 200 may include a substrate 210, horizontal supporting layers 221, 222, and 223, a vertical supporting structure 230, as well as a plurality of capacitor structures 240.

The substrate 210 may be a semiconductor substrate, such as a bulk semiconductor, a semiconductor-on-insulator (SOI) substrate, or the like. In some embodiments, the substrate 210 may have a multilayered structure.

Some elements are formed within or on the substrate 210. For example, transistors, conductive traces, contact plugs and/or other elements may be formed within or on the substrate 210.

In some embodiments, the horizontal supporting layer 221 may be disposed on the substrate 210. In some embodiments, the horizontal supporting layer 221 may also be referred to as a lower horizontal supporting layer.

In some embodiments, the horizontal supporting layer 222 may be disposed on the substrate 210. In some embodiments, the horizontal supporting layer 222 may be disposed over the horizontal supporting layer 221. In some embodiments, the horizontal supporting layer 222 may also be referred to as a middle horizontal supporting layer.

In some embodiments, the horizontal supporting layer 223 may be disposed on the substrate 210. In some embodiments, the horizontal supporting layer 223 may be disposed over the horizontal supporting layer 222. In some embodiments, the horizontal supporting layer 223 may also be referred to as an upper horizontal supporting layer.

In some embodiments, the horizontal supporting layers 221, 222, and 223 may be spaced apart from each other. In some embodiments, the horizontal supporting layers 221, 222, and 223 may be utilized to define the patterns of a capacitor dielectric and an upper electrode of the capacitor structure 240.

Each of the horizontal supporting layers 221, 222, and 223 may include Si₃N₄, SiO₂, N₂OSi₂, N₂OSi₂, or other suitable materials. In some embodiments, the horizontal supporting layers 221, 222, and 223 may have the same material.

The vertical supporting structure 230 may be disposed on the substrate 210. In some embodiments, the vertical supporting structure 230 may be configured to support the horizontal supporting layers 221, 222, and 223. In some embodiments, the vertical supporting structure 230 may be disposed at a peripheral region (not annotated) of the semiconductor device 200.

In some embodiments, the pillar 231 may be configured to support the horizontal supporting layer 222. In some embodiments, the pillar 231 may extend between the horizontal supporting layers 221 and 222. In some embodiments, the pillar 231 may connect the horizontal supporting layers 221 and 222. In some embodiments, the pillar 231 may be in contact with the horizontal supporting layer 221. In some embodiments, the pillar 231 may be in contact with the horizontal supporting layer 222. In some embodiments, the pillar 231 may include a dielectric material. In some embodiments, the pillar 231 may include a conductive material.

In some embodiments, the pillar 232 may be configured to support the horizontal supporting layer 223. In some embodiments, the pillar 232 may extend between the horizontal supporting layers 222 and 223. In some embodiments, the pillar 232 may connect the horizontal supporting layers 222 and 223. In some embodiments, the pillar 232 may be in contact with the horizontal supporting layer 222. In some embodiments, the pillar 232 may be in contact with the horizontal supporting layer 223. In some embodiments, the pillar 232 may include a dielectric material. In some embodiments, the pillar 232 may include a conductive material.

The pillar 231 may have a width W1 along the X-direction. The pillar 232 may have a width W2 along the X-direction. In some embodiments, the width W1 of the pillar 231 may be different from the width W2 of the pillar 232 along the X-direction. In some embodiments, the width W1 of the pillar 231 may be greater than the width W2 of the pillar 232 along the X-direction. The ratio between the width W1 and the width W2 may range from about 1.1 to about 10, such as 1.1, 1.5, 1.8, 2, 3, 5, or 10. When the pillar 231 has a greater width, the pillar 231 can withstand greater weight and provide a more rigid structure.

Each of the capacitor structures 240 may be disposed within an opening defined by the horizontal supporting layers 221, 222, and/or 223. In some embodiments, the capacitor structure 240 may be disposed within an array region (not annotated) of the semiconductor device 200. Each of the capacitor structures 240 may include a capacitor electrode 241, a capacitor dielectric 242, and a capacitor electrode 243. In some embodiments, the capacitor electrode 241 may be disposed on and in contact with a lateral surface (not annotated in the figures) of the horizontal supporting layer 221. In some embodiments, the capacitor electrode 241 may be disposed on and in contact with a lateral surface (not annotated in the figures) of the horizontal supporting layer 222. In some embodiments, the capacitor electrode 241 may be disposed on and in contact with a lateral surface (not annotated in the figures) of the horizontal supporting layer 223.

In some embodiments, the capacitor electrode 241 may be spaced apart from the vertical supporting structure 230. In some embodiments, the capacitor electrode 241 may be spaced apart from the pillar 231. In some embodiments, the capacitor electrode 241 may be spaced apart from the pillar 232. In some embodiments, the capacitor electrode 241 may be spaced apart from the vertical supporting structure 230 by the capacitor dielectric 242. In some embodiments, the capacitor electrode 241 may be spaced apart from the vertical supporting structure 230 by the capacitor electrode 243. The capacitor electrode 241 may include a conductive material. The capacitor electrode 241 may also be referred to as a lower capacitor electrode.

In some embodiments, the capacitor dielectric 242 may be conformally disposed on the capacitor electrode 241. The capacitor dielectric 242 may be disposed on and in contact with the horizontal supporting layer 221. The capacitor dielectric 242 may be disposed on and in contact with the horizontal supporting layer 222. The capacitor dielectric 242 may be disposed on and in contact with the horizontal supporting layer 223. In some embodiments, the capacitor dielectric 242 may be disposed on and in contact with the vertical supporting structure 230. In some embodiments, the capacitor dielectric 242 may be disposed on and in contact with the pillar 231. In some embodiments, the capacitor dielectric 242 may be disposed on and in contact with the pillar 232. The capacitor dielectric 242 may include silicon oxide, tungsten oxide, copper oxide, aluminum oxide, hafnium oxide, or the like.

The capacitor electrode 243 may be disposed on the capacitor dielectric 242. The capacitor electrode 243 may be spaced apart from the capacitor electrode 241 by the capacitor dielectric 242. The capacitor electrode 243 may be spaced apart from the horizontal supporting layers 221, 222, and 223 by the capacitor dielectric 242. In some embodiments, the capacitor electrode 243 may be spaced apart from the vertical supporting structure 230. In some embodiments, the capacitor electrode 243 may be spaced apart from the pillar 231. In some embodiments, the capacitor electrode 243 may be spaced apart from the pillar 232. The capacitor electrode 243 may include conductive material.

In the embodiments of the present disclosure, a semiconductor device (e.g., 200) may include a vertical supporting structure (e.g., 230) to connect horizontal supporting layers (e.g., horizontal supporting layers 221, 222, and/or 223). The vertical supporting structure can reinforce the overall structure of the semiconductor device, which thereby enhances the semiconductor device manufacturing yield.

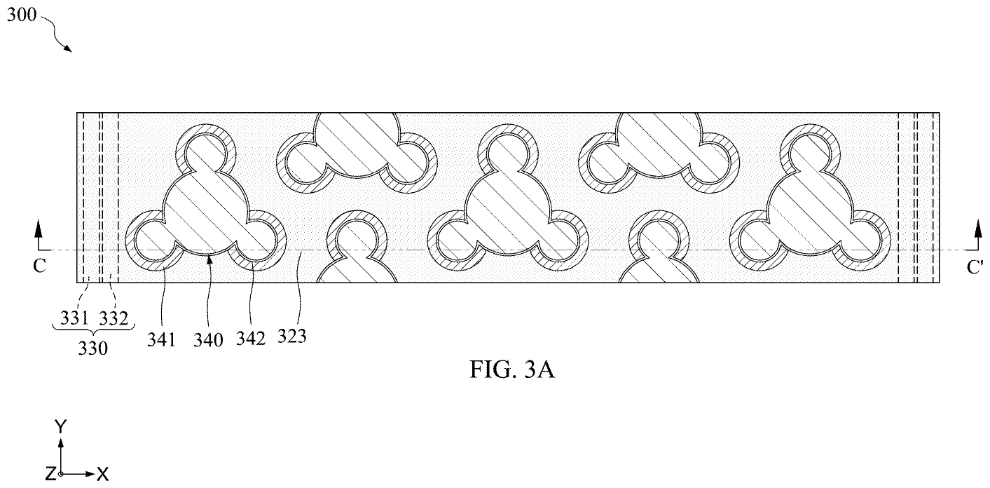

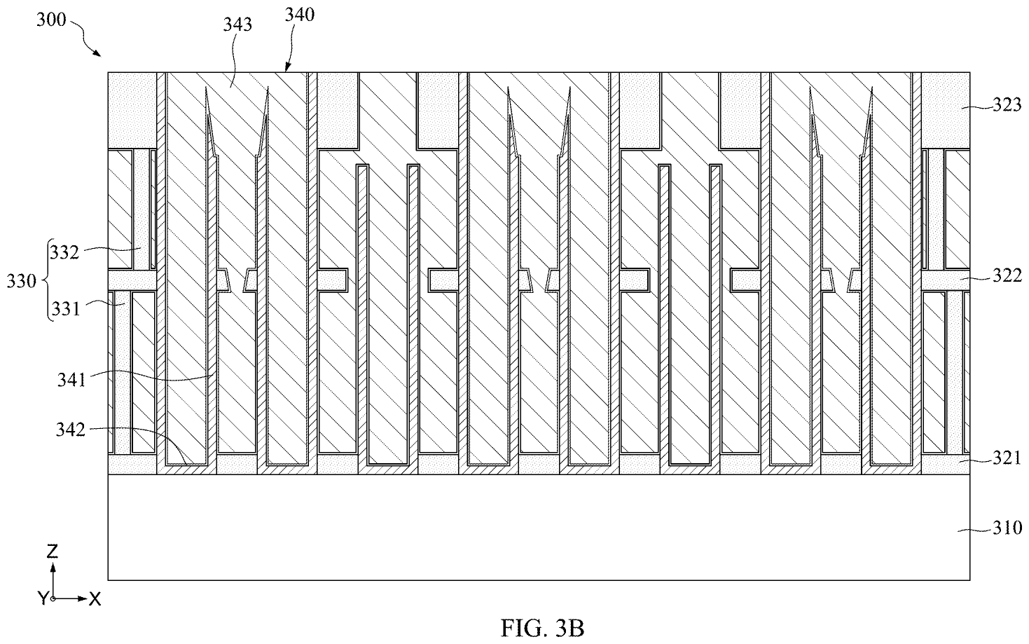

Referring to FIG. 3A and FIG. 3B, FIG. 3A is a top view of a semiconductor device 300, and FIG. 3B is a cross-sectional view along line B-B′ of the semiconductor device 300 as shown in FIG. 3A, in accordance with some embodiments of the present disclosure.

In some embodiments, the semiconductor device 300 may include a substrate 310, horizontal supporting layers 321, 322, and 323, a vertical supporting structure 330, as well as a plurality of capacitor structures 340.

The substrate 310 may be a semiconductor substrate, such as a bulk semiconductor, a semiconductor-on-insulator (SOI) substrate, or the like. In some embodiments, the substrate 310 may have a multilayered structure.

Some elements are formed within or on the substrate 310. For example, transistors, conductive traces, contact plugs and/or other elements may be formed within or on the substrate 310.

In some embodiments, the horizontal supporting layer 321 may be disposed on the substrate 310. In some embodiments, the horizontal supporting layer 321 may also be referred to as a lower horizontal supporting layer.

In some embodiments, the horizontal supporting layer 322 may be disposed on the substrate 310. In some embodiments, the horizontal supporting layer 322 may be disposed over the horizontal supporting layer 321. In some embodiments, the horizontal supporting layer 322 may also be referred to as a middle horizontal supporting layer.

In some embodiments, the horizontal supporting layer 323 may be disposed on the substrate 310. In some embodiments, the horizontal supporting layer 323 may be disposed over the horizontal supporting layer 322. In some embodiments, the horizontal supporting layer 323 may also be referred to as an upper horizontal supporting layer.

In some embodiments, the horizontal supporting layers 321, 322, and 323 may be spaced apart from each other. In some embodiments, the horizontal supporting layers 321, 322, and 323 may be utilized to define the patterns of a capacitor dielectric and an upper electrode of the capacitor structure 340.

Each of the horizontal supporting layers 321, 322, and 323 may include Si₃N₄, SiO₂, N₂OSi₂, N₂OSi₂, or other suitable materials. In some embodiments, the horizontal supporting layers 321, 322, and 323 may have the same material.

The vertical supporting structure 330 may be disposed on the substrate 310. In some embodiments, the vertical supporting structure 330 may be configured to support the horizontal supporting layers 321, 322, and 323. In some embodiments, the vertical supporting structure 330 may be disposed at a peripheral region (not annotated) of the semiconductor device 300.

In some embodiments, the pillar 331 may be configured to support the horizontal supporting layer 322. In some embodiments, the pillar 331 may extend between the horizontal supporting layers 321 and 322. In some embodiments, the pillar 331 may connect the horizontal supporting layers 321 and 322. In some embodiments, the pillar 331 may be in contact with the horizontal supporting layer 321. In some embodiments, the pillar 331 may be in contact with the horizontal supporting layer 322. In some embodiments, the pillar 331 may include a dielectric material. In some embodiments, the pillar 331 may include a conductive material.

In some embodiments, the pillar 332 may be configured to support the horizontal supporting layer 323. In some embodiments, the pillar 332 may extend between the horizontal supporting layers 323 and 323. In some embodiments, the pillar 332 may connect the horizontal supporting layers 323 and 323. In some embodiments, the pillar 332 may be in contact with the horizontal supporting layer 322. In some embodiments, the pillar 332 may be in contact with the horizontal supporting layer 323. In some embodiments, the pillar 332 may include a dielectric material. In some embodiments, the pillar 332 may include a conductive material.

In some embodiments, the pillar 331 may be free from overlapping the pillar 332 along the Z-direction. In some embodiments, the pillar 331 may be misaligned with the pillar 332 along the Z direction. In other embodiments, the pillar 331 may partially overlap the pillar 332 along the Z direction. In some embodiments, the pillar 332 is closer to a lower electrode of the capacitor structure 340 than the pillar 331 is. In other embodiments, the pillar 332 may be located within the array region of the semiconductor device 300. For example, the pillar 332 may be located within the capacitor structure 340, while the pillar 331 may surround the capacitor structure 340, which may provide a relatively rigid structure based on the pattern of the capacitor structure 340.

Each of the capacitor structures 340 may be disposed within an opening defined by the horizontal supporting layers 321, 322, and/or 323. In some embodiments, the capacitor structure 340 may be disposed within an array region (not annotated) of the semiconductor device 300. Each of the capacitor structures 340 may include a capacitor electrode 341, a capacitor dielectric 342, and a capacitor electrode 343. In some embodiments, the capacitor electrode 341 may be disposed on and in contact with a lateral surface (not annotated in the figures) of the horizontal supporting layer 321. In some embodiments, the capacitor electrode 341 may be disposed on and in contact with a lateral surface (not annotated in the figures) of the horizontal supporting layer 322. In some embodiments, the capacitor electrode 341 may be disposed on and in contact with a lateral surface (not annotated in the figures) of the horizontal supporting layer 323.

In some embodiments, the capacitor electrode 341 may be spaced apart from the vertical supporting structure 330. In some embodiments, the capacitor electrode 341 may be spaced apart from the pillar 331. In some embodiments, the capacitor electrode 341 may be spaced apart from the pillar 332. In some embodiments, the capacitor electrode 341 may be spaced apart from the vertical supporting structure 330 by the capacitor dielectric 342. In some embodiments, the capacitor electrode 341 may be spaced apart from the vertical supporting structure 330 by the capacitor electrode 343. The capacitor electrode 341 may include a conductive material. The capacitor electrode 341 may also be referred to as a lower capacitor electrode.

In some embodiments, the capacitor dielectric 342 may be conformally disposed on the capacitor electrode 341. The capacitor dielectric 342 may be disposed on and in contact with the horizontal supporting layer 321. The capacitor dielectric 342 may be disposed on and in contact with the horizontal supporting layer 322. The capacitor dielectric 342 may be disposed on and in contact with the horizontal supporting layer 323. In some embodiments, the capacitor dielectric 342 may be disposed on and in contact with the vertical supporting structure 330. In some embodiments, the capacitor dielectric 342 may be disposed on and in contact with the pillar 331. In some embodiments, the capacitor dielectric 342 may be disposed on and in contact with the pillar 332. The capacitor dielectric 342 may include silicon oxide, tungsten oxide, copper oxide, aluminum oxide, hafnium oxide, or the like.

The capacitor electrode 343 may be disposed on the capacitor dielectric 342. The capacitor electrode 343 may be spaced apart from the capacitor electrode 341 by the capacitor dielectric 342. The capacitor electrode 343 may be spaced apart from the horizontal supporting layers 321, 322, and 323 by the capacitor dielectric 342. In some embodiments, the capacitor electrode 343 may be spaced apart from the vertical supporting structure 330. In some embodiments, the capacitor electrode 343 may be spaced apart from the pillar 331. In some embodiments, the capacitor electrode 343 may be spaced apart from the pillar 332. The capacitor electrode 343 may include conductive material.

In the embodiments of the present disclosure, a semiconductor device (e.g., 300) may include a vertical supporting structure (e.g., 330) to connect horizontal supporting layers (e.g., 321, 322, and/or 323). The vertical supporting structure can reinforce the overall structure of the semiconductor device, which thereby enhances the semiconductor device manufacturing yield.

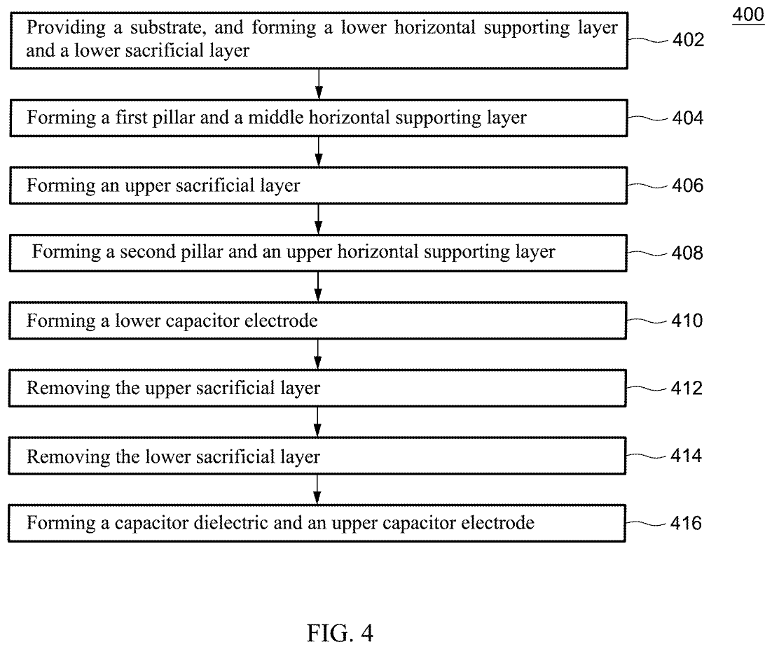

FIG. 4 is a flowchart illustrating a method 400 of manufacturing a semiconductor device, in accordance with some embodiments of the present disclosure.

Referring to FIG. 4, the method 400 begins with operation 402 in which a substrate is provided. A lower horizontal supporting layer may be formed on the substrate. A lower sacrificial layer may be formed on the lower horizontal supporting layer.

The method 400 continues with operation 404 in which the lower sacrificial layer may be patterned to form first openings exposing the lower horizontal supporting layer. First pillars may be formed to fill the first openings. A middle horizontal supporting layer may be formed to cover the lower sacrificial layer.

The method 400 continues with operation 406 in which an upper sacrificial layer may be formed to cover the middle horizontal supporting layer.

The method 400 continues with operation 408 in which the upper sacrificial layer may be patterned to form second openings exposing the middle horizontal supporting layer. Second pillars may be formed to fill the second openings. A vertical supporting structure may be produced. An upper horizontal supporting layer may be formed to cover the upper sacrificial layer.

The method 400 continues with operation 410 in which a lower capacitor electrode may be formed within a third opening defined by the sacrificial layers and the horizontal supporting layers.

The method 400 continues with operation 412 in which the upper sacrificial layer may be removed to expose a portion of the middle horizontal supporting layer.

The method 400 continues with operation 414 in which the lower sacrificial layer may be removed to expose a portion of the lower horizontal supporting layer.

The method 400 continues with operation 416 in which a capacitor dielectric and an upper capacitor electrode may be formed to produce a semiconductor device.

The method 400 is merely an example, and is not intended to limit the present disclosure beyond what is explicitly recited in the claims. Additional operations can be provided before, during, or after each operation of the method 400, and some operations described can be replaced, eliminated, or reordered for additional embodiments of the method. In some embodiments, the method 400 can include further operations not depicted in FIG. 4. In some embodiments, the method 300 can include one or more operations depicted in FIG. 4.

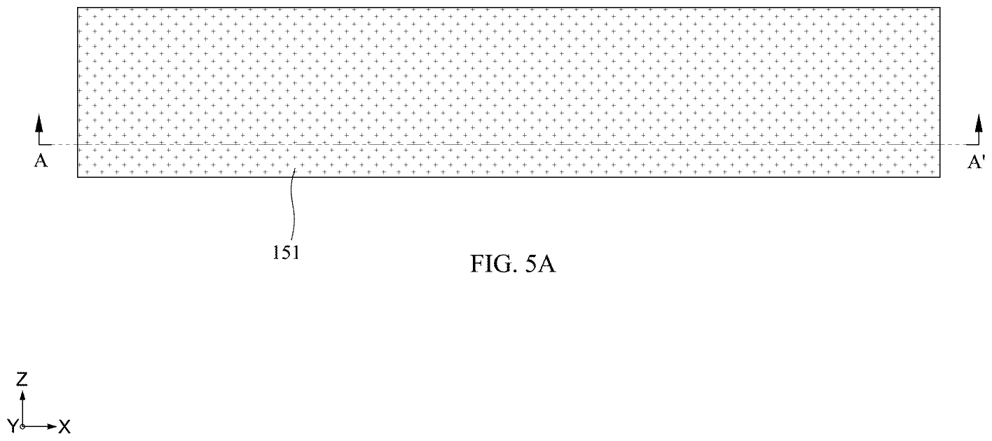

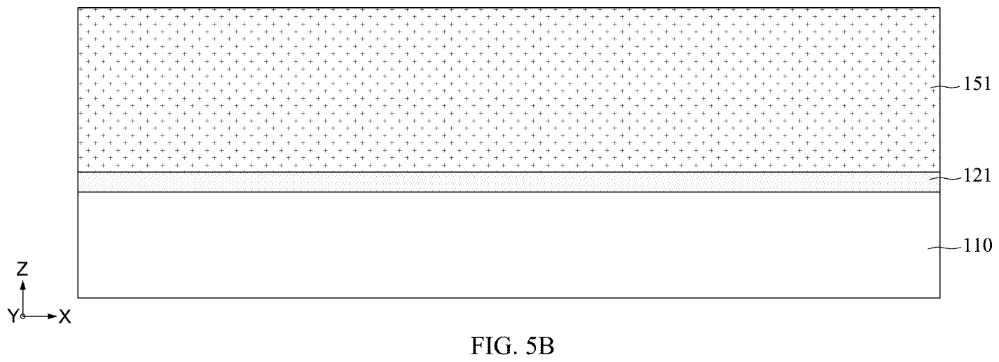

FIG. 5A to FIG. 17A and FIG. 5B to FIG. 17B illustrate stages of an example of a method for manufacturing a semiconductor device according to some embodiments of the present disclosure. In some embodiments, the semiconductor device 100 may be manufactured through the operations described with respect to FIG. 5A to FIG. 17A and FIG. 5B to FIG. 17B.

Referring to FIG. 5A and FIG. 5B, a substrate 110 may be provided. A horizontal supporting layer 121 may be formed on the substrate 110. A sacrificial layer 151 may be formed on the horizontal supporting layer 121. The sacrificial layer 151 may include silicon oxide (SiO₂), and for example, may include Towable oxide (FOX), tonen silazene (TOSZ), undoped silica glass (USG), borosilica glass (BSG), phosphosilica glass (PSG), Eorophosphosilica glass (BPSG), plasma enhanced tetraethyl orthosilicate (PE-TEOS), or fluoride silicate glass (FSG). In some embodiments, the material of the sacrificial layer 151 may be different from that of the horizontal supporting layer 121. Each of the horizontal supporting layer 121 and the sacrificial layer 151 may be formed by chemical vapor deposition (CVD), atomic layer deposition (ALD), physical vapor deposition (PVD), low-pressure chemical vapor deposition (LPCVD), plasma-enhanced CND (PECVD), or other suitable processes.

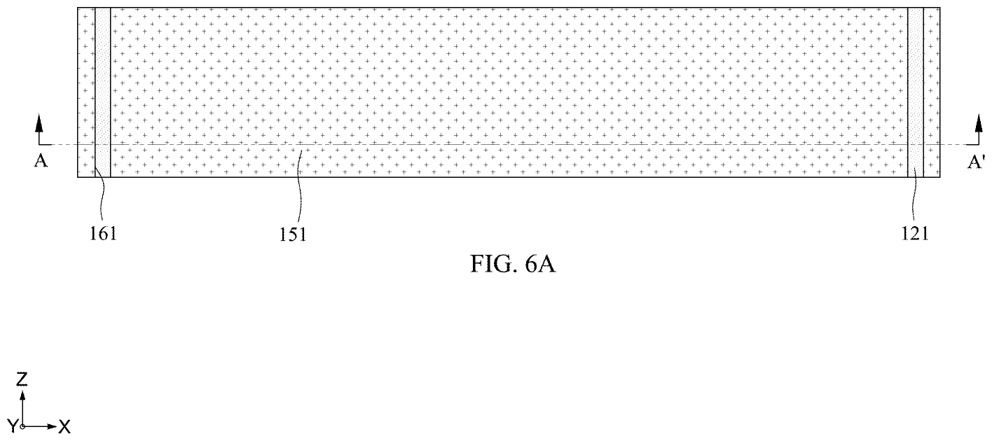

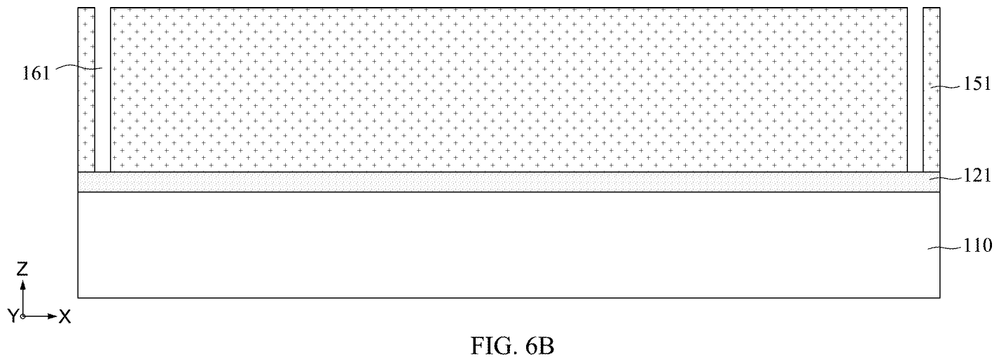

Referring to FIG. 6A and FIG. 6B, the sacrificial layer 151 may be patterned to form openings 161. In some embodiments, the openings 161 may be formed on a peripheral region of a semiconductor device. The opening 161 may expose the horizontal supporting layer 121. The opening 161 may extend along the Y-direction. An etching technique may be performed to form the openings.

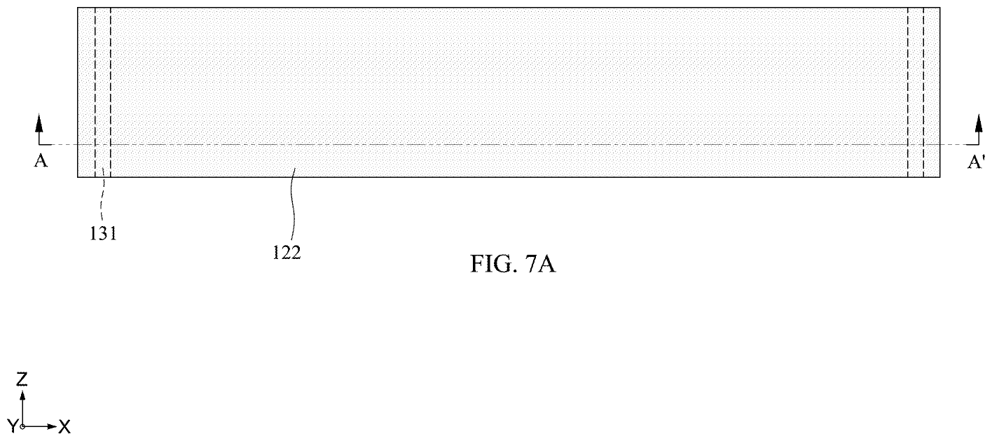

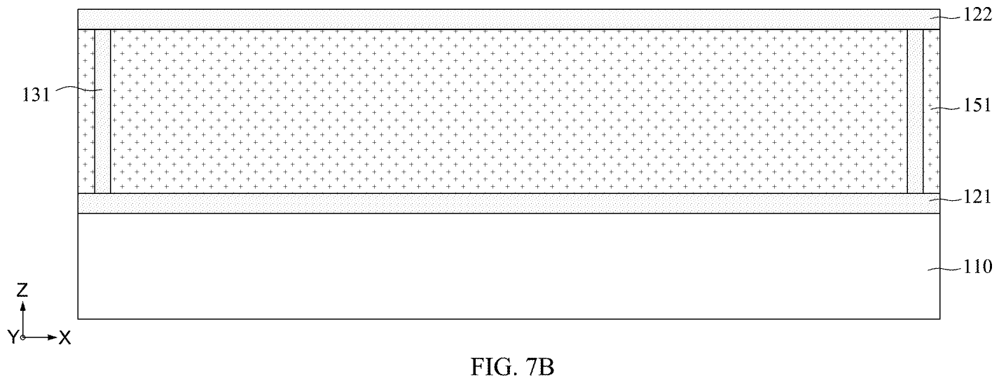

Referring to FIG. 7A and FIG. 7B, a pillar 131 and a horizontal supporting layer 122 may be formed. In some embodiments, the pillar 131 may be formed to fill the opening 161. The horizontal supporting layer 122 may be formed to cover the sacrificial layer 151. In some embodiments, the horizontal supporting layer 122 and the pillar 131 may have the same material. The horizontal supporting layer 122 and the pillar 131 may be formed by CVD, ALD, PVD, LPCVD, PECVD, or other suitable processes.

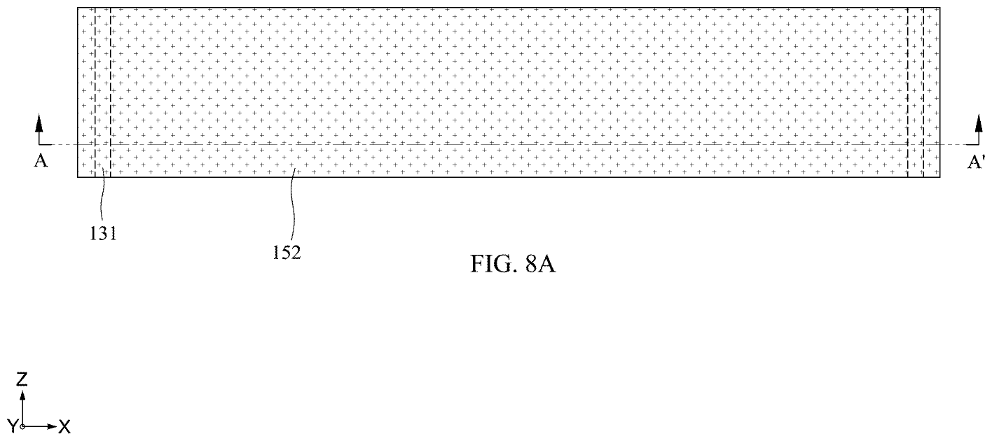

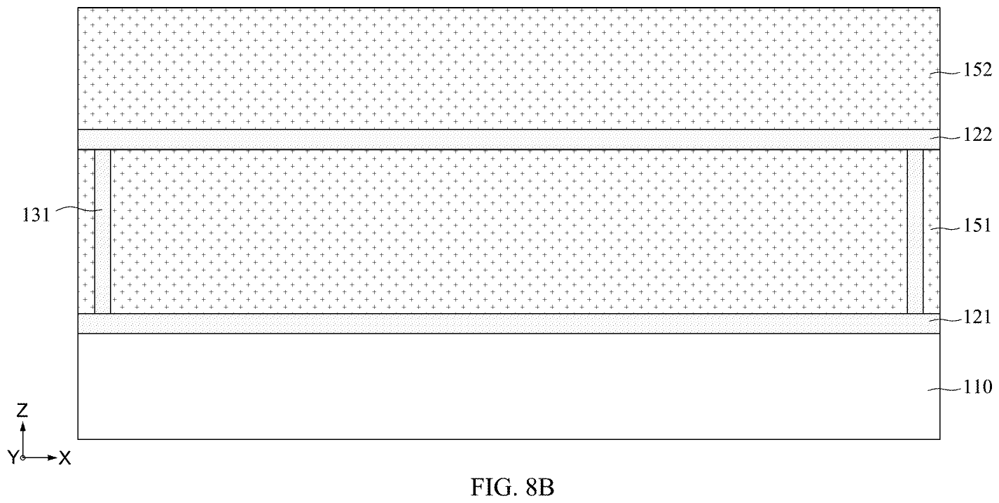

Referring to FIG. 8A and FIG. 8B, a sacrificial layer 152 may be formed to cover the horizontal supporting layer 122 and the pillar 131. The sacrificial layer 152 may include silicon oxide, such as FOX, TOSZ, USG, BSG, PSG, BPSG, PE-TEOS or FSG. In some embodiments, the material of the sacrificial layer 152 may be the same as that of the sacrificial layer 151. In some embodiments, the material of the sacrificial layer 152 may be different from that of the horizontal supporting layer 122. For example, the sacrificial layer 152 may be made of silicon oxide, and the horizontal supporting layer 122 may be made of silicon nitride. The sacrificial layer 152 may be formed by CVD, ALD, PVD, LPCVD, PECVD, or other suitable processes.

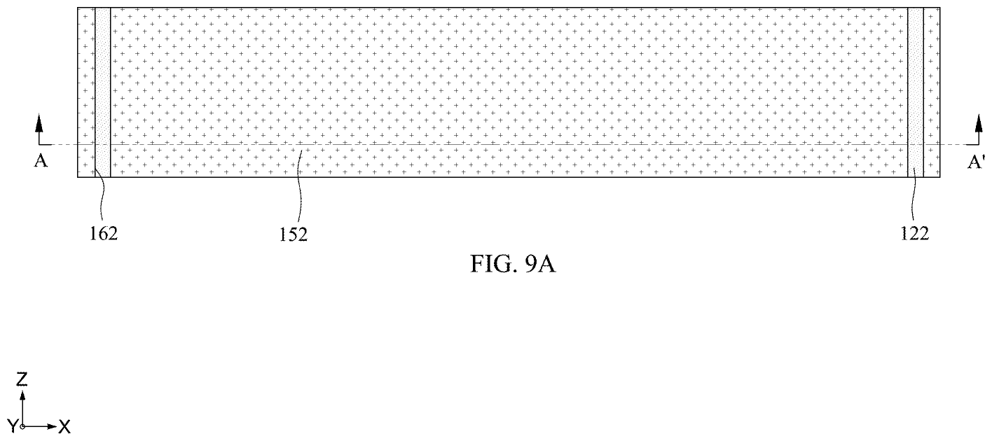

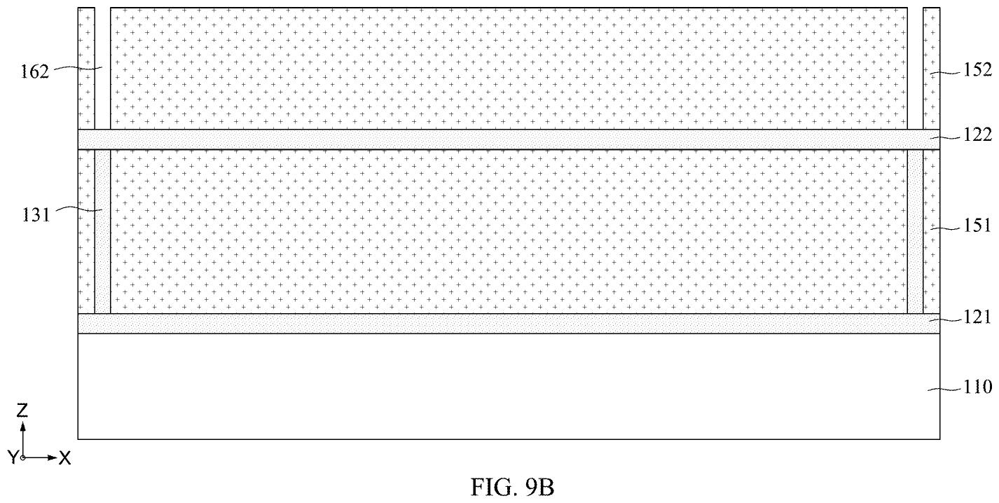

Referring to FIG. 9A and FIG. 9B, the sacrificial layer 152 may be patterned to form openings 162. In some embodiments, the openings 162 may be formed on a peripheral region of a semiconductor device. The opening 162 may expose the horizontal supporting layer 122. The opening 162 may extend along the Y-direction. An etching technique may be performed to form the openings.

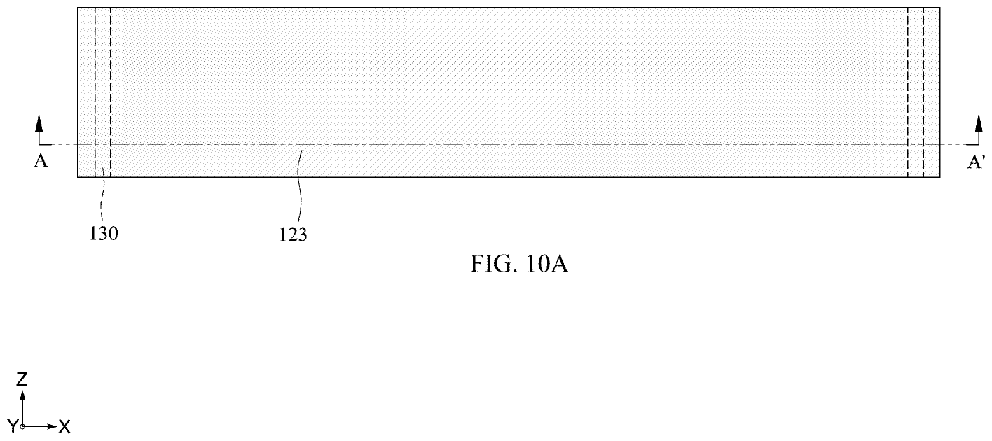

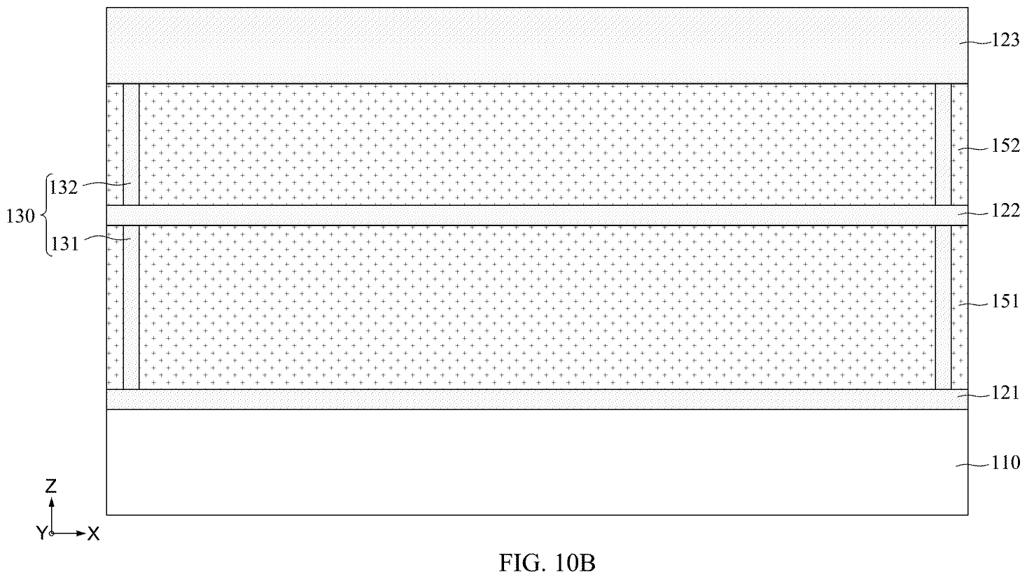

Referring to FIG. 10A and FIG. 10B, a pillar 132 and a horizontal supporting layer 123 may be formed, and a vertical supporting structure 130 may be produced. In some embodiments, the pillar 132 may be formed to fill the opening 162. The horizontal supporting layer 123 may be formed to cover the sacrificial layer 152. In some embodiments, the horizontal supporting layer 123 and the pillar 132 may have the same material. The horizontal supporting layer 123 and the pillar 132 may be formed by CVD, ALD, PVD, LPCVD, PECVD, or other suitable processes.

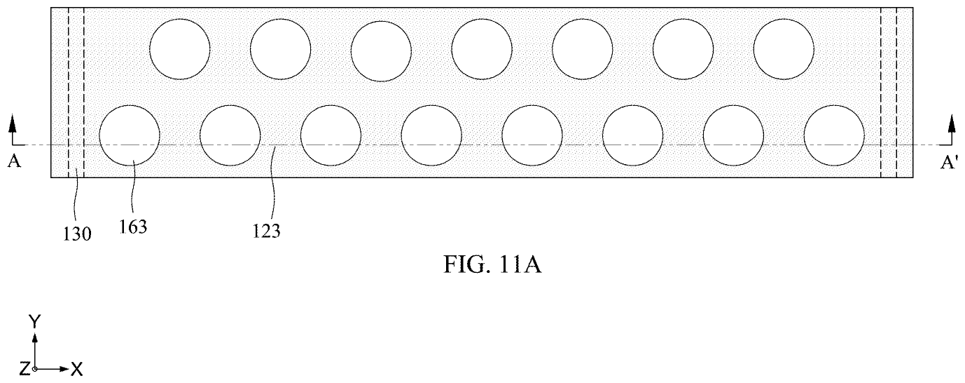

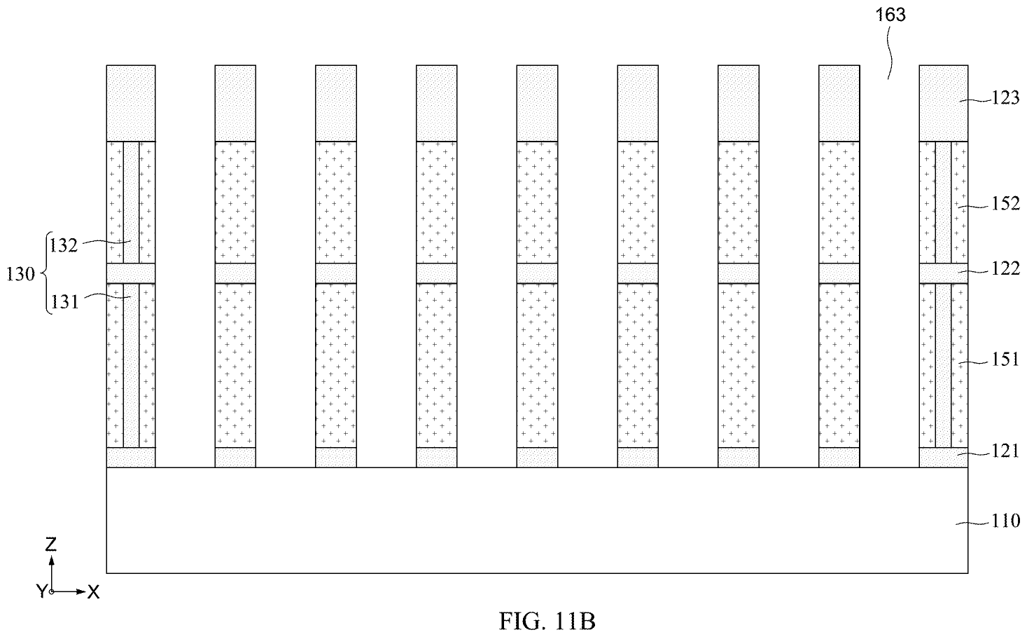

Referring to FIG. 11A and FIG. 11B, the horizontal supporting layers 121, 122, and 123 as well as the sacrificial layer 151 and sacrificial layer 152 may be patterned to form openings 163. The opening 163 may expose the substrate 110. In some embodiments, the opening 163 may have a circular profile, an elliptical profile, or other suitable profiles in a top view. In some embodiments, the vertical supporting structure 130 may be covered by the sacrificial layer 151. In some embodiments, the vertical supporting structure 130 may be covered by the sacrificial layer 152. The opening 163 may be formed by, for example, a dry etching.

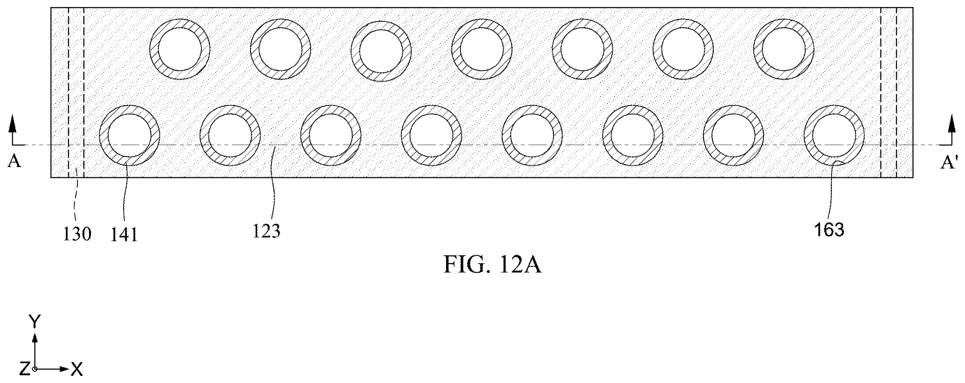

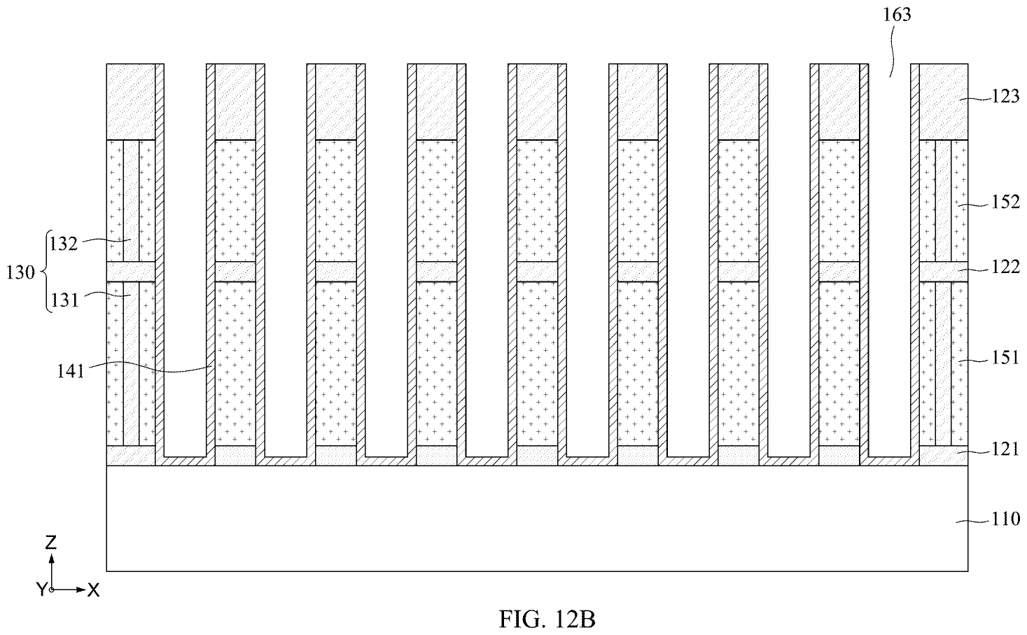

Referring to FIG. 12A and FIG. 12B, a capacitor electrode 141 may be formed within the opening 163. The capacitor electrode 141 may be formed on and in contact with a lateral surface of the horizontal supporting layer 121. The capacitor electrode 141 may be formed on and in contact with a lateral surface of the horizontal supporting layer 122. The capacitor electrode 141 may be formed on and in contact with a lateral surface of the horizontal supporting layer 123. The capacitor electrode 141 may be formed on and in contact with a lateral surface of the sacrificial layer 151. The capacitor electrode 141 may be formed on and in contact with a lateral surface of the sacrificial layer 152. In some embodiments, the capacitor electrode 141 be spaced apart from the pillar 131 by the sacrificial layer 151. In some embodiments, the capacitor electrode 141 be spaced apart from the pillar 132 by the sacrificial layer 152. The capacitor electrode 141 may be formed by CVD, ALD, PVD, LPCVD, PECVD, or other suitable processes.

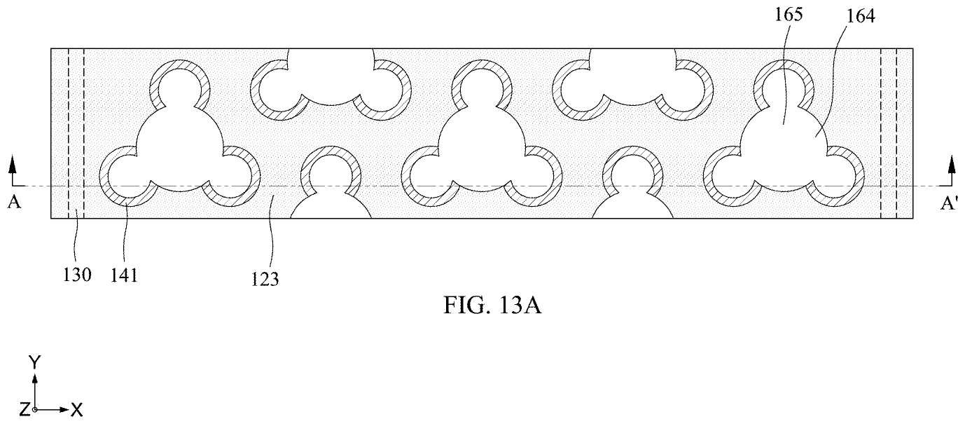

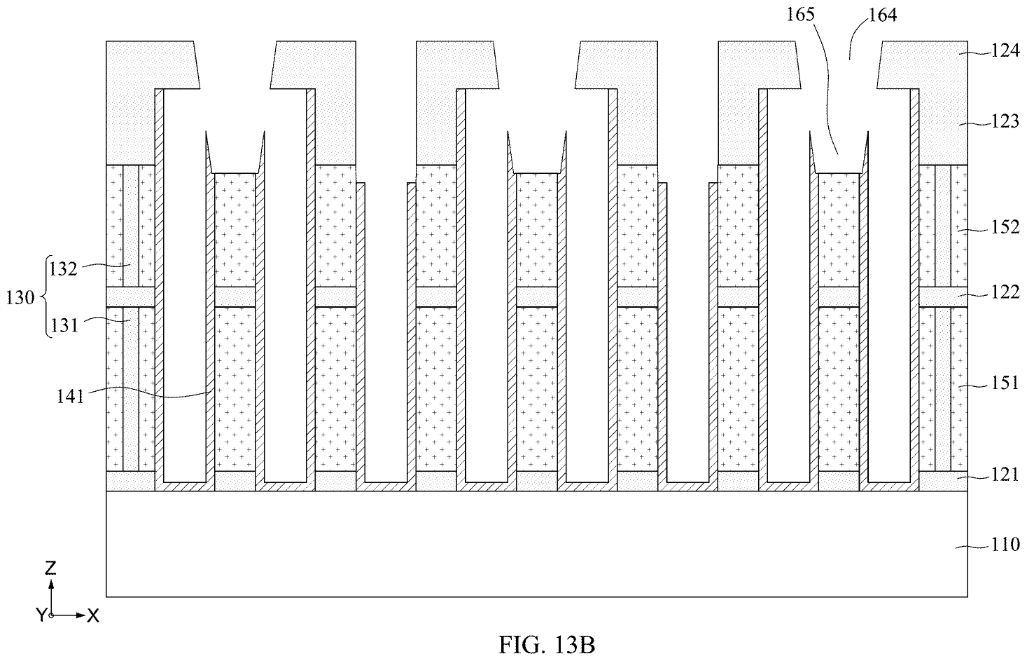

Referring to FIG. 13A and FIG. 13B, a cap dielectric 124 may be formed over the horizontal supporting layer 123. In some embodiments, the material of the cap dielectric 124 may be the same as that of the horizontal supporting layer 123. The cap dielectric 124 may define openings 164 over the horizontal supporting layer 123. In some embodiments, a portion of the horizontal supporting layer 123 exposed by the opening 164 may be removed to form openings 165. In some embodiments, the opening 165 may expose the sacrificial layer 152. It should be noted that the cap dielectric 124 is omitted from FIG. 13A for brevity.

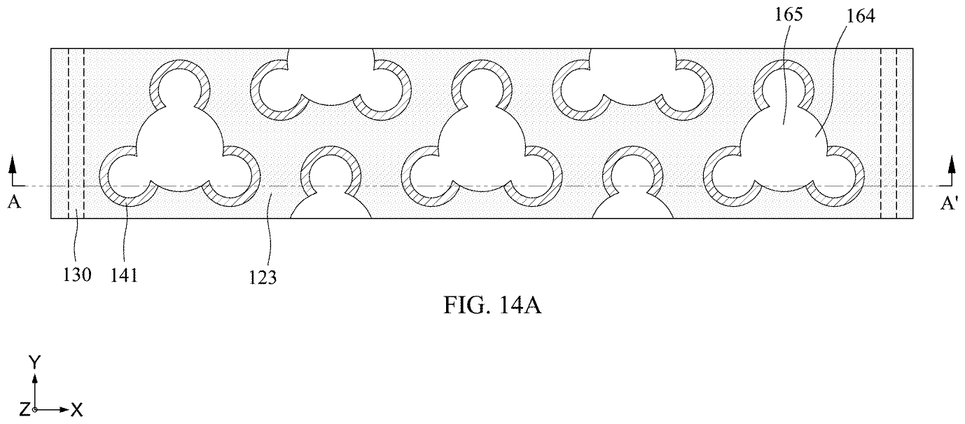

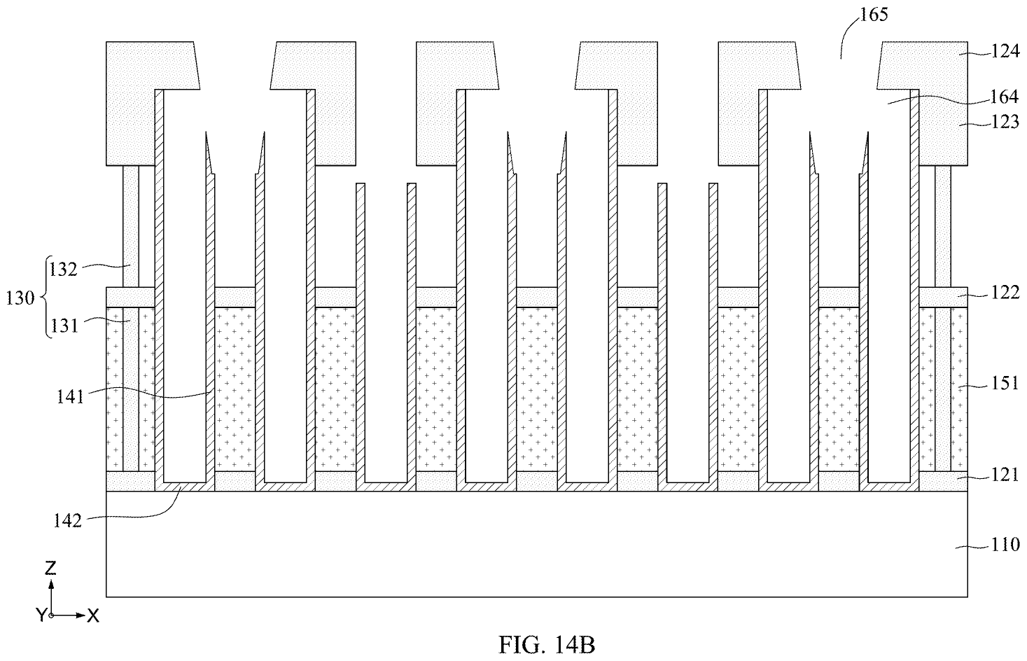

Referring to FIG. 14A and FIG. 14B, the sacrificial layer 152 may be removed. In some embodiments, the upper surface of the horizontal supporting layer 122 may be exposed. In some embodiments, the sacrificial layer 152 may be removed by, for example, a wet etching process.

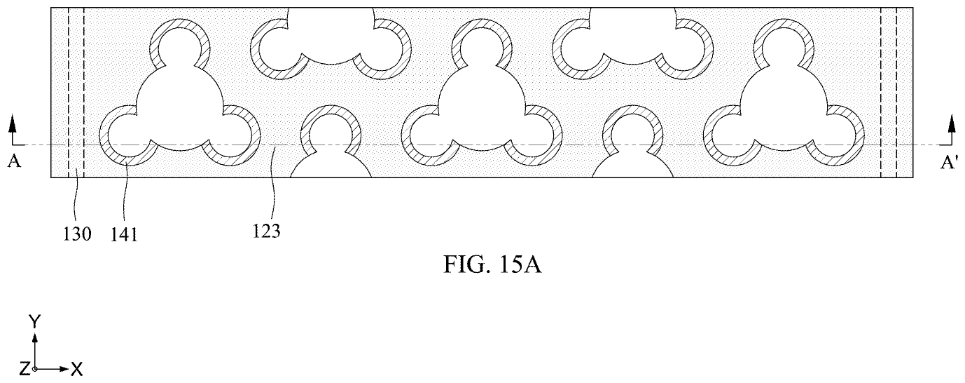

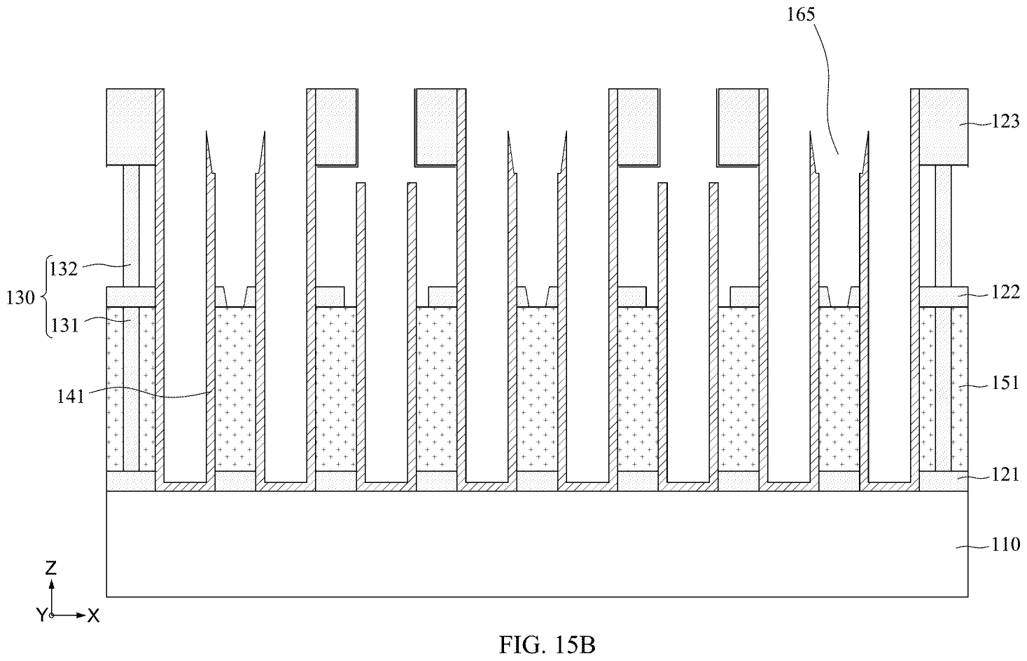

Referring to FIG. 15A and FIG. 15B, the cap dielectric 124 may be removed. In some embodiments, a portion of the horizontal supporting layer 122 exposed by the opening 165 may be removed. A portion of the sacrificial layer 151 may be exposed by the horizontal supporting layer 122.

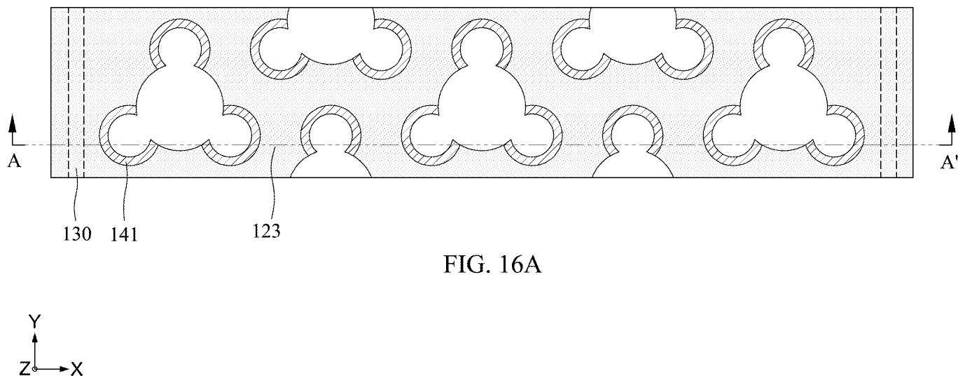

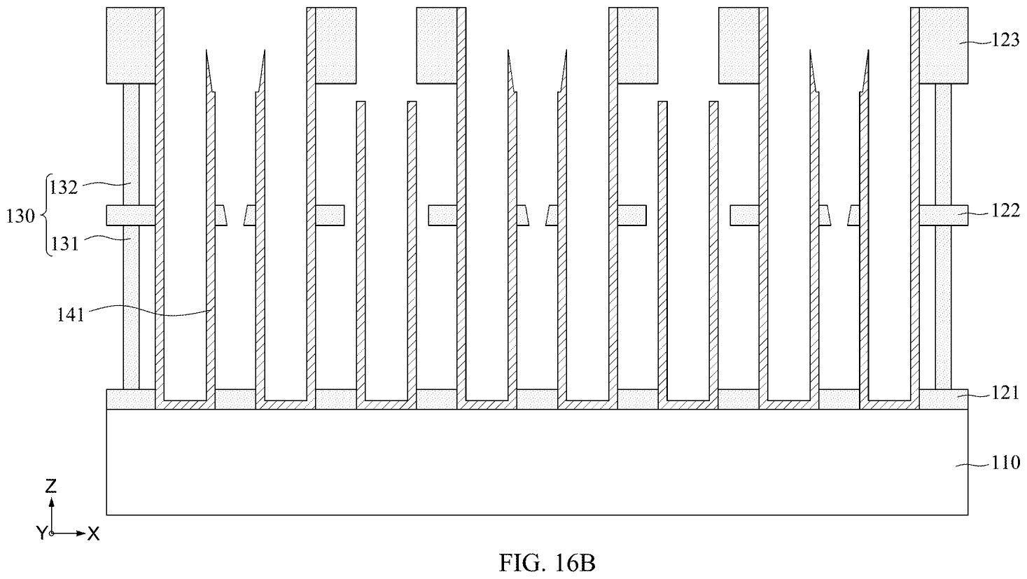

Referring to FIG. 16A and FIG. 16B, the sacrificial layer 151 may be removed. In some embodiments, the upper surface of the horizontal supporting layer 121 may be exposed. In some embodiments, the sacrificial layer 151 may be removed by, for example, a wet etching process.

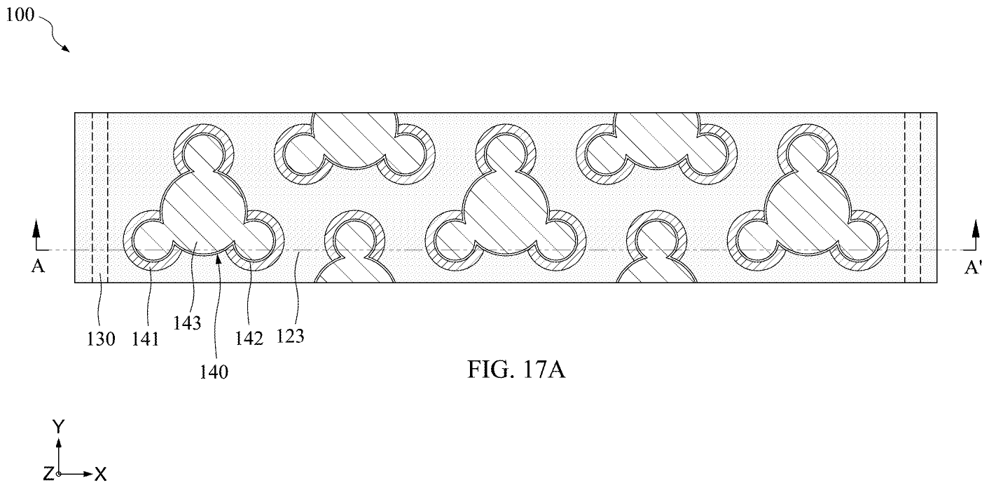

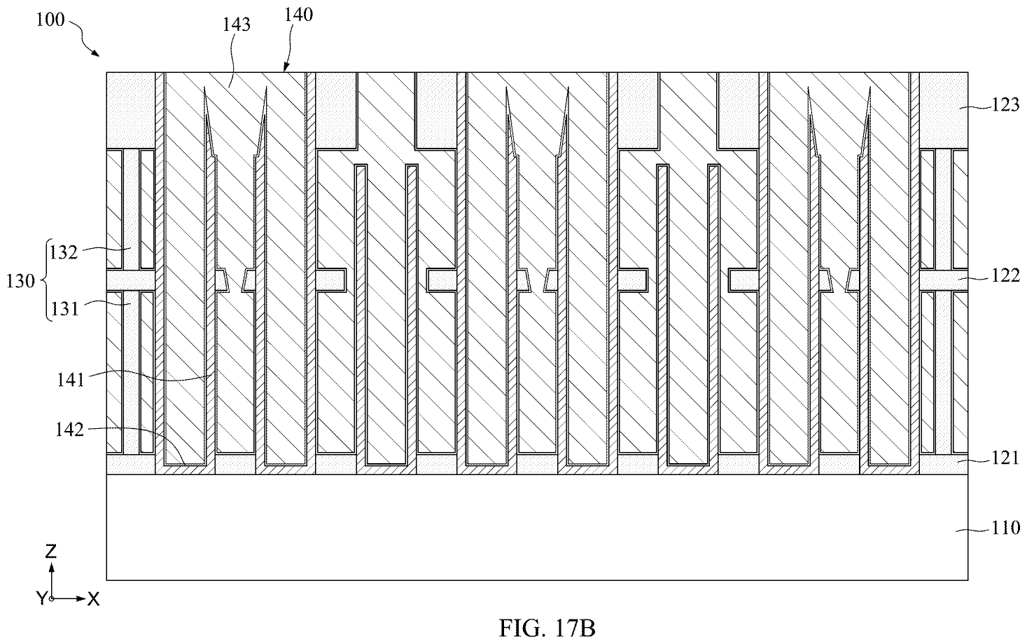

Referring to FIG. 17A and FIG. 17B, a capacitor dielectric 142 and a capacitor electrode 143 may be formed, which thereby produces a semiconductor device, such as the semiconductor device 100 as shown in FIG. 1A and FIG. 1B. The capacitor dielectric 142 may be conformally formed on the horizontal supporting layers 121, 122, and 123, pillars 131 and 132, as well as the capacitor electrode 141. The capacitor electrode 143 may be formed on the capacitor dielectric 142 to define the capacitor structure 140.

When the sacrificial layer 151 and/or sacrificial layer 152 are removed (e.g., the stage shown in FIG. 14A to FIG. 16A as well as FIG. 14B to FIG. 16B), the framework of the intermediate structure in these stages is relatively weak, which causes the capacitor electrode 141 to collapse. In this embodiment, the pillar 131 and pillar 132 are formed to connect the horizontal supporting layers 121, 122, and 123, enhancing the framework of the intermediate structure.

One aspect of the present disclosure provides a semiconductor device. The semiconductor device includes a substrate, a lower horizontal supporting layer, an upper horizontal supporting layer, a vertical supporting structure, and a first capacitor electrode. The lower horizontal supporting layer is disposed on the substrate. The upper horizontal supporting layer is disposed on the lower horizontal supporting layer. The vertical supporting structure extends between the lower horizontal supporting layer and the upper horizontal supporting layer. The first capacitor electrode is disposed on the substrate and extends from the lower horizontal supporting layer to the upper horizontal supporting layer.

Another aspect of the present disclosure provides another semiconductor device. The semiconductor device includes a substrate, a lower horizontal supporting layer, an upper horizontal supporting layer, a first vertical supporting structure, a second vertical supporting structure, and a plurality of capacitor structures. The lower horizontal supporting layer is disposed on the substrate. The upper horizontal supporting layer is disposed on the lower horizontal supporting layer. The first vertical supporting structure extends between the lower horizontal supporting layer and the upper horizontal supporting layer. The second vertical supporting structure extends between the lower horizontal supporting layer and the upper horizontal supporting layer. Each of the capacitor structure is disposed between the first vertical supporting structure and the second vertical supporting structure.

Another aspect of the present disclosure provides a method of manufacturing a semiconductor device. The method includes providing a substrate. The method also includes forming a first horizontal supporting layer on the substrate. The method further includes forming a first sacrificial layer on the first horizontal supporting layer. In addition, the method includes removing a portion of the first sacrificial layer to form a first opening. The method also includes forming a first pillar filling the first opening and a second horizontal supporting layer on the first sacrificial layer. The method further includes patterning the second horizontal supporting layer, the first sacrificial layer, and the first horizontal supporting layer to define a second opening. The method includes forming a first capacitor electrode within the second opening and removing the first sacrificial layer.

The embodiments of the present disclosure provide a semiconductor device. The semiconductor device may include a vertical supporting structure to connect horizontal supporting layers. The vertical supporting structure can reinforce the overall structure of a semiconductor device. For example, when sacrificial layers are removed to define a space for upper capacitor electrode, the framework composed of horizontal supporting layers and a lower capacitor electrode is prone to collapse, resulting in a lower semiconductor device manufacturing yield. In such a condition, the vertical supporting structure can provide a more rigid structure to prevent the framework from collapse. As a result, the semiconductor device manufacturing yield can be enhanced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a lower horizontal supporting layer disposed on the substrate;
an upper horizontal supporting layer disposed on the lower horizontal supporting layer;
a vertical supporting structure extending between the lower horizontal supporting layer and the upper horizontal supporting layer; and
a first capacitor electrode disposed on the substrate and extending from the lower horizontal supporting layer to the upper horizontal supporting layer.

2. The semiconductor device of claim 1, wherein the first capacitor electrode is spaced apart from the vertical supporting structure.

3. The semiconductor device of claim 1, further comprising:
a capacitor dielectric; and
a second capacitor electrode spaced apart from the first capacitor electrode by the capacitor dielectric,
wherein the second capacitor electrode is spaced apart from the vertical supporting structure.

4. The semiconductor device of claim 3, wherein the capacitor dielectric is in contact with the vertical supporting structure, and the first capacitor electrode is spaced apart from the vertical supporting structure by the capacitor dielectric and the second capacitor electrode.

5. The semiconductor device of claim 1, further comprising:
a middle horizontal supporting layer disposed between the lower horizontal supporting layer and the upper horizontal supporting layer;
wherein the vertical supporting structure comprises a first pillar disposed between the lower horizontal supporting layer and the middle horizontal supporting layer;
wherein the vertical supporting structure comprises a second pillar disposed between the upper horizontal supporting layer and the middle horizontal supporting layer;
wherein a dimension of the first pillar is different from a dimension of the second pillar; and
wherein the first pillar is free from vertically overlapping the second pillar.

6. The semiconductor device of claim 1, wherein the first capacitor electrode is in contact with the lower horizontal supporting layer.

7. The semiconductor device of claim 1, wherein a material of the vertical supporting structure is the same as that of the lower horizontal supporting layer.

8. A semiconductor device, comprising:
a substrate;
a lower horizontal supporting layer disposed on the substrate;
an upper horizontal supporting layer disposed on the lower horizontal supporting layer;
a first vertical supporting structure extending between the lower horizontal supporting layer and the upper horizontal supporting layer;
a second vertical supporting structure extending between the lower horizontal supporting layer and the upper horizontal supporting layer; and
a plurality of capacitor structures disposed between the first vertical supporting structure and the second vertical supporting structure.

9. The semiconductor device of claim 8, wherein the plurality of capacitor structures comprises a first capacitor comprising a first capacitor electrode spaced apart from the first vertical supporting structure, the first capacitor further comprises a capacitor dielectric and a second capacitor electrode spaced apart from the first capacitor electrode by the capacitor dielectric, the second capacitor electrode is spaced apart from the first vertical supporting structure.

10. The semiconductor device of claim 9, wherein the capacitor dielectric of the first capacitor is in contact with the first vertical supporting structure.

11. The semiconductor device of claim 9, wherein the first capacitor electrode is spaced apart from the first vertical supporting structure by the capacitor dielectric and the second capacitor electrode.

12. The semiconductor device of claim 8, further comprising:
a middle horizontal supporting layer disposed between the lower horizontal supporting layer and the upper horizontal supporting layer;
wherein the first vertical supporting structure comprises a first pillar disposed between the lower horizontal supporting layer and the middle horizontal supporting layer;
wherein the first vertical supporting structure comprises a second pillar disposed between the upper horizontal supporting layer and the middle horizontal supporting layer;
wherein a dimension of the first pillar is different from a dimension of the second pillar.

13. The semiconductor device of claim 9, wherein the first capacitor electrode is in contact with the lower horizontal supporting layer.

14. The semiconductor device of claim 9, wherein a material of the first vertical supporting structure is the same as that of the lower horizontal supporting layer.

15. A method of manufacturing a semiconductor device, comprising:
providing a substrate;
forming a first horizontal supporting layer on the substrate;
forming a first sacrificial layer on the first horizontal supporting layer;
removing the first sacrificial layer to form a first opening;
forming a first pillar filling the first opening;
forming a second horizontal supporting layer on the first sacrificial layer;
patterning the second horizontal supporting layer, the first sacrificial layer, and the first horizontal supporting layer to define a second opening;
forming a first capacitor electrode within the second opening; and
removing the first sacrificial layer.

16. The method of claim 15, wherein a material of the first pillar is different from a material of the first sacrificial layer.

17. The method of claim 15, wherein a material of the first pillar is the same as a material of the second horizontal supporting layer.

18. The method of claim 15, further comprising:
forming a capacitor dielectric on the first capacitor electrode and on the first pillar; and
forming a second capacitor electrode on the capacitor dielectric.

19. The method of claim 15, further comprising:
forming a second sacrificial layer on the second horizontal supporting layer;
removing the second sacrificial layer to form a third opening;
forming a second pillar filling the third opening;
forming a third horizontal supporting layer on the second sacrificial layer,
patterning the third horizontal supporting layer and the first sacrificial layer to define the second opening; and
removing the second sacrificial layer;
wherein a dimension of the first pillar is different from a dimension of the second pillar.

20. The method of claim 15, wherein the first capacitor electrode is spaced apart from the first pillar by the first sacrificial layer.
